(19) United States
(12) Patent Application Publication
(10) Pub. No.: US 2025/0118347 A1
(43) Pub. Date: Apr. 10, 2025

(54) SEMICONDUCTOR DEVICE HAVING TIMING CONTROL CIRCUIT

(71) Applicant: MICRON TECHNOLOGY, INC., BOISE, ID (US)

(72) Inventors: Hideo Shimizu, Sagamihara (JP); Yutaka Uemura, Sagamihara (JP)

(73) Assignee: MICRON TECHNOLOGY, INC., Boise, ID (US)

(21) Appl. No.: 18/756,232

(22) Filed: Jun. 27, 2024

Related U.S. Application Data
(60) Provisional application No. 63/588,247, filed on Oct. 5, 2023.

(51) Int. Cl. G11C 7/22; G11C 7/10

(52) U.S. Cl. CPC G11C 7/222; G11C 7/1048; G11C 7/1096

(57) ABSTRACT

An example apparatus includes a data bus including a first portion having a timing domain which is controlled based on a first timing signal and further including a second portion having a timing domain which is controlled based on a second timing signal, and a data transfer circuit coupled to the data bus, the data transfer circuit including a data driver between the first portion of the data bus and the second portion of the data bus and a timing control circuit coupled to the data driver. The timing control circuit includes a variable delay to add an amount of delay to a first control signal to generate a second control signal. The data driver is configured to drive data from the second portion of the data bus to the first portion of the data bus responsive to the second control signal.

### CROSS REFERENCE TO RELATED APPLICATION(S)

This application claims priority to U.S. Provisional Application No. 63/588,247, filed Oct. 5, 2023. The aforementioned application is incorporated herein by reference, in its entirety, for any purpose.

### BACKGROUND

A semiconductor memory device such as a DRAM (Dynamic Random Access Memory) performs an operation synchronized with a clock signal supplied from outside. However, a write data supplied from outside at the time of a write operation is supplied synchronously with a data strobe signal instead of the clock signal. Therefore, it may be preferred that the write data has a timing in a timing domain that is controlled based on the clock signal inside the semiconductor memory device.

### BRIEF DESCRIPTION OF THE DRAWINGS

FIG. 1 is a block diagram showing a configuration of a semiconductor device according to one embodiment of the present disclosure;

FIG. 2 is a circuit diagram of a transfer circuit;

FIG. 3A is an example of a circuit diagram of a timing control circuit;

FIG. 3B is another example of the circuit diagram of the timing control circuit; and

FIG. 4 is a timing chart for explaining an operation of the transfer circuit.

### DETAILED DESCRIPTION

Various embodiments of the present disclosure will be explained below in detail with reference to the accompanying drawings. The following detailed description refers to the accompanying drawings that show, by way of illustration, specific aspects, and various embodiments of the present disclosure. The detailed description provides sufficient detail to enable those skilled in the art to practice these embodiments of the present disclosure. Other embodiments may be utilized, and structural, logical, and electrical changes may be made without departing from the scope of the present disclosure. The various embodiments disclosed herein are not necessary mutually exclusive, as some disclosed embodiments can be combined with one or more other disclosed embodiments to form new embodiments.

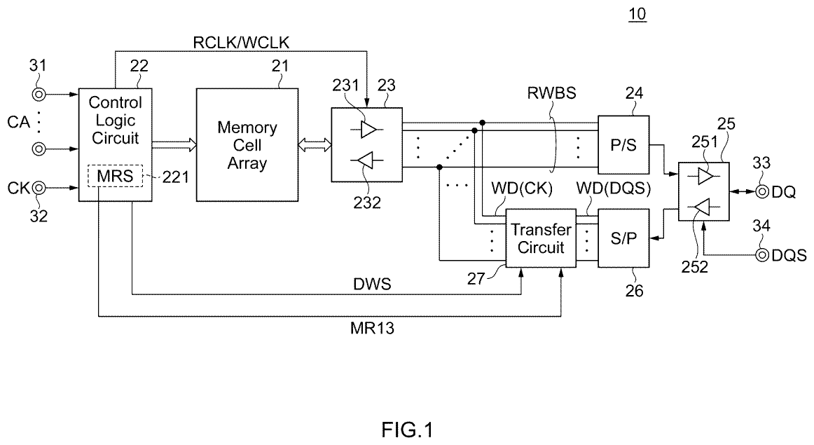

FIG. 1 is a block diagram showing a configuration of a semiconductor device 10 according to one embodiment of the present disclosure. The semiconductor device 10 shown in FIG. 1 is a DRAM and has a memory cell array 21 including a plurality of memory cells. The semiconductor device 10 has a command address terminal 31, a clock terminal 32, a data terminal 33, and a data strobe terminal 34. A command address signal CA and a clock signal CK are input from outside to the command address terminal 31 and the clock terminal 32, respectively. The command address signal CA and the clock signal CK are supplied to a control logic circuit 22.

When the command address signal CA indicates a read operation, the control logic circuit 22 performs an operation to read a data from a designated address in the memory cell array 21. The read data having been read from the memory cell array 21 is output to outside from the data terminal 33 via a read amplifier 231 included in an amplifier circuit 23, a parallel/serial conversion circuit 24, and an I/O circuit 25. The operation of the read amplifier 231 is performed synchronously with a read clock signal RCLK supplied from the control logic circuit 22. The read clock signal RCLK's timing domain is controlled based on the clock signal CK. The amplifier circuit 23 is coupled to the parallel/serial conversion circuit 24 by a plurality of read/write buses RWBS. A plurality of read data supplied in parallel through the read/write buses RWBS are converted into a serial data by the parallel/serial conversion circuit 24. The I/O circuit 25 includes an output buffer circuit 251. Accordingly, at the time of a read operation, a plurality of read data are output serially from the data terminal 33.

When the command address signal CA indicates a write operation, the control logic circuit 22 performs an operation to write a write data input to the data terminal 33 from outside. At the time of a write operation, a plurality of write data supplied serially to the data terminal 33 are supplied to a serial/parallel conversion circuit 26 via the I/O circuit 25. The serial/parallel conversion circuit 26 converts the serial plural write data into parallel data. The write data converted into the parallel data are supplied to the read/write buses RWBS via a transfer circuit 27. The write data transferred to the read/write buses RWBS are written to a designated address in the memory cell array 21 via a write amplifier 232 included in the amplifier circuit 23. The operation of the write amplifier 232 is performed synchronously with a write clock signal WCLK supplied from the control logic circuit 22. The write clock signal WCLK's timing domain is controlled based on the clock signal CK.

The I/O circuit 25 includes an input receiver circuit 252. The input receiver circuit 252 captures the write data input to the data terminal 33 synchronously with a data strobe signal DQS. Accordingly, the serial write data input to the serial/parallel conversion circuit 26 and the parallel write data output from the serial/parallel conversion circuit 26 are synchronous with the data strobe signal DQS. The transfer circuit 27 transfers the parallel write data output from the serial/parallel conversion circuit 26 to the read/write buses RWBS.

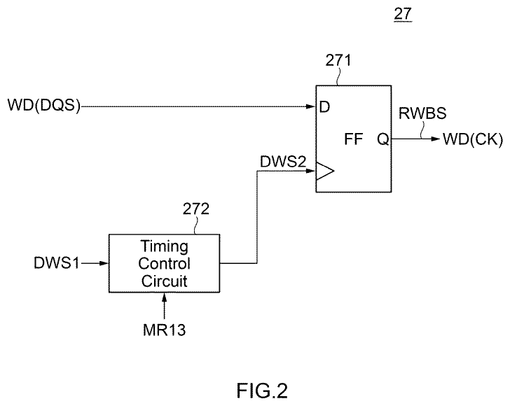

FIG. 2 is a circuit diagram of the transfer circuit 27. Only circuits corresponding to one bit of parallel write data WD are shown in FIG. 2. As shown in FIG. 2, the transfer circuit 27 includes a flip-flop circuit 271 that latches write data WD(DQS) output from the serial/parallel conversion circuit 26 synchronously with a timing signal DWS2, and a timing control circuit 272 that generates the timing signal DWS2 based on a timing signal DWS1. The flip-flop circuit 271 may be replaced by a through latch circuit or a tristate buffer.

The write data WD(DQS) are synchronous with the data strobe signal DQS. The timing signal DWS1 is output from the control logic circuit 22 at a predetermined timing of a/the timing domain that is controlled based on the clock signal CK when the command address signal CA indicates a write operation. The timing control circuit 272 receives the timing signal DWS1 and delays the timing signal DWS1 to generate the timing signal DWS2. An amount of delay of the timing control circuit 272, that is, a time elapsed after the timing signal DWS1 is activated until the timing signal DWS2 is activated is variable according to a mode signal MR13. The mode signal MR13 is a signal set in a mode register 221 included in the control logic circuit 22 and indirectly indicates the frequency of the clock signal CK. The timing control circuit 272 increases the amount of delay as the frequency of the clock signal CK indicated by the mode signal MR13 is lower and decreases the amount of delay as the frequency of the clock signal CK indicated by the mode signal MR13 is higher. Accordingly, the timing of latching of the write data WD(DQS) by the flip-flop circuit 271 is later as the frequency of the clock signal CK indicated by the mode signal MR13 is lower, and the timing of latching of the write data WD(DQS) by the flip-flop circuit 271 is earlier as the frequency of the clock signal CK indicated by the mode signal MR13 is higher. Write data WD(CK) latched by the flip-flop circuit 271 are output to the read/write buses RWBS. As a result, the write data WD(CK) are output to the read/write buses RWBS in the timing domain of the clock signal CK. As described above, the transfer circuit 27 functions to convert the write data WD(DQS) in a timing domain of the data strobe signal DQS into the write data WD(CK) in the timing domain of the clock signal CK.

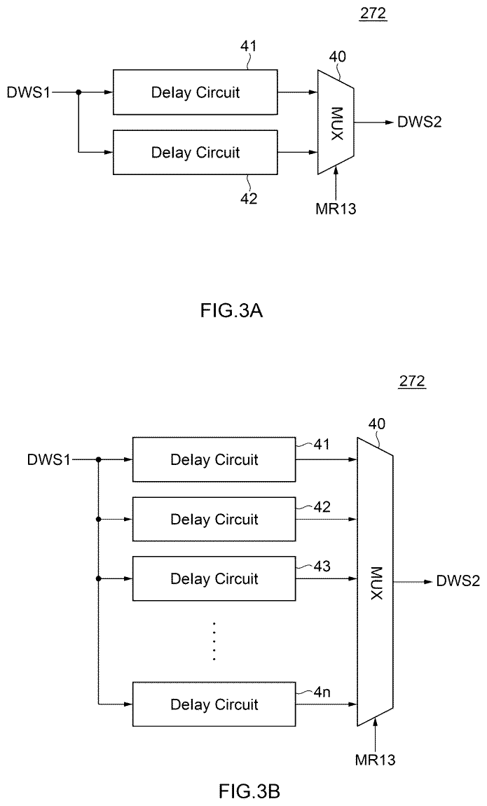

FIG. 3A is an example of a circuit diagram of the timing control circuit 272. The timing control circuit 272 according to the example shown in FIG. 3A includes two delay circuits 41 and 42 that receive the timing signal DWS1, and a multiplexer 40 that selects one of outputs of the delay circuits 41 and 42. The timing signal DWS1 is supplied in common to the delay circuits 41 and 42. The amounts of delay of the delay circuits 41 and 42 are mutually different. Accordingly, times elapsed after the timing signal DWS1 is activated until the timing signal DWS2 is output from the delay circuits 41 and 42 are mutually different. For example, the amount of delay of the delay circuit 42 is shorter than that of the delay circuit 41. The timing signals DWS2 output from the delay circuits 41 and 42 are supplied to the multiplexer 40. The multiplexer 40 selects one of the timing signals DWS2 output from the delay circuits 41 and 42 according to the mode signal MR13. For example, the multiplexer 40 selects the timing signal DWS2 output from the delay circuit 41 when the frequency of the clock signal CK indicated by the mode signal MR13 is lower than a predetermined frequency, and the multiplexer 40 selects the timing signal DWS2 output from the delay circuit 42 when the frequency of the clock signal CK indicated by the mode signal MR13 is higher than the predetermined frequency.

FIG. 3B is another example of the circuit diagram of the timing control circuit 272. The timing control circuit 272 according to the example shown in FIG. 3B includes n delay circuits 41 to 4n that receive the timing signal DWS1, and the multiplexer 40 that selects one of outputs of the delay circuits 41 to 4n. The timing signal DWS1 is supplied in common to the delay circuits 41 to 4n. The amounts of delay of the delay circuits 41 to 4n are mutually different. For example, the amount of delay of the delay circuit 42 is shorter than that of the delay circuit 41, and the amount of delay of the delay circuit 43 is shorter than that of the delay circuit 42. Accordingly, times elapsed after the timing signal DWS1 is activated until the timing signals DWS2 are output from the delay circuits 41 to 4n are mutually different. As described above, with use of a larger number of the delay circuits 41 to 4n, the time elapsed after the timing signal DWS1 is activated until the timing signal DWS2 is activated can be more finely adjusted. For example, the multiplexer 40 selects the timing signal DWS2 output from the delay circuit 41 when the frequency of the clock signal CK indicated by the mode signal MR13 is in a first range, the multiplexer 40 selects the timing signal DWS2 output from the delay circuit 42 when the frequency of the clock signal CK indicated by the mode signal MR13 is in a second range higher than the first range, and the multiplexer 40 selects the timing signal DWS2 output from the delay circuit 43 when the frequency of the clock signal CK indicated by the mode signal MR13 is in a third range higher than the second range.

A write leveling operation is performed to the semiconductor device 10 at the manufacturing stage. When the write leveling operation is performed, the timings of the clock signal CK and the data strobe signal DQS ideally match. In some examples, the timings may be referred to as timing domains. However, a certain range of deviation of the data strobe signal DQS from the clock signal CK after the write leveling operation is allowed in specifications. Specifically, specifications tDQSS and tDQSoffset are defined and the total value of tDQSS and tDQSoffset is a range in which the data strobe signal DQS can be deviated from the clock signal CK. The absolute values of tDQSS and tDQSoffset are proportional to a period tCK of the clock signal CK. When tCK=0.25 ns (nanosecond) and WRITE Preamble is 4 tCK as an example, tDQSS=±0.625 tCK and tDQSoffset=±0.5 tCK. When tCK=1.01 ns and WRITE Preamble is 2 tCK as another example, tDQSS=+0.375 tCK and tDQSoffset=±0.5 tCK. As described above, since the absolute values of tDQSS and tDQSoffset are proportional to the period tCK of the clock signal CK, the absolute value of a timing difference between the timing signal DWS2 having a timing of a/the timing domain that is controlled based on the clock signal CK and the write data WD(DQS) synchronous with the data strobe signal DQS increases as the period tCK of the clock signal CK is longer. Accordingly, the absolute value of the timing difference between the timing signal DWS2 and the write data WD(DQS) is the largest when the period tCK of the clock signal CK is set to the maximum value (tCKmax). Therefore, the activation timing of the timing signal DWS2 is adjusted by the timing control circuit 272 to enable the write data WD(DQS) to be captured by the flip-flop circuit 271 even when the timing difference between the timing signal DWS2 and the write data WD(DQS) is the largest.

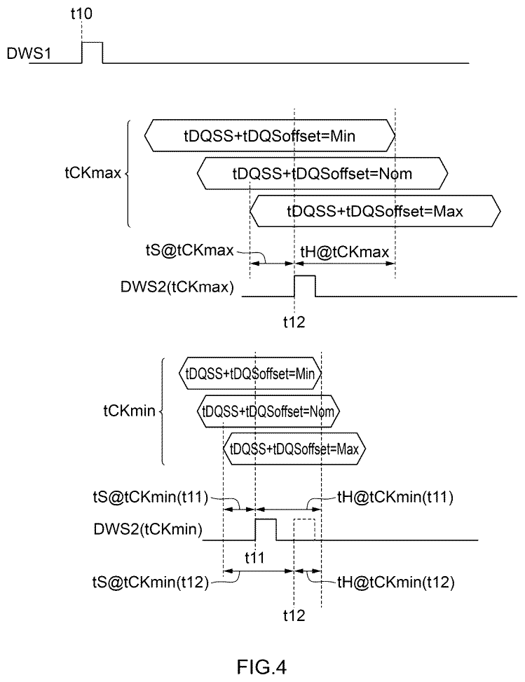

FIG. 4 is a timing chart for explaining an operation of the transfer circuit 27. FIG. 4 shows Valid Windows of the write data WD(DQS) in a case (tCKmax) in which the period tCK of the clock signal CK is the longest and Valid Windows of the write data WD(DQS) in a case (tCKmin) in which the period tCK of the clock signal CK is the shortest.

As shown in FIG. 4, when the timing signal DWS1 is activated at a time t10, the timing signal DWS2 is activated at a time t12 in the case (tCKmax) in which the period tCK of the clock signal CK is the longest, and the timing signal DWS2 is activated at a time t11 earlier than the time t12 in the case (tCKmin) in which the period tCK of the clock signal CK is the shortest. This is realized, for example, by selecting the delay circuit 41 shown in FIG. 3A in the case (tCKmax) in which the period tCK of the clock signal CK is the longest and selecting the delay circuit 42 shown in FIG. 3A in the case (tCKmin) in which the period tCK of the clock signal CK is the shortest.

In the case (tCKmax) in which the period tCK of the clock signal CK is the longest, a setup margin tS@tCKmax of the timing signal DWS2 is defined by a period from the start timing of the Valid Window of the write data WD(DQS) in the case in which tDQSS+tDQSoffset is the largest to the activation timing of the timing signal DWS2. In the case (tCKmax) in which the period tCK of the clock signal CK is the longest, a hold margin tH@tCKmax of the timing signal DWS2 is defined by a period from the activation timing of the timing signal DWS2 to the end timing of the Valid Window of the write data WD(DQS) in the case in which tDQSS+tDQSoffset is the smallest. As described above, since the Valid Windows of the write data WD(DQS) are large in the case (tCKmax) in which the period tCK of the clock signal CK is the longest, a sufficient hold margin tH@tCKmax of the timing signal DWS2 can be provided even when a long setup margin tS@tCKmax of the timing signal DWS2 is set.

Even when the timing signal DWS2 is activated at the time t12 in the case (tCKmin) in which the period tCK of the clock signal CK is the shortest, a sufficient setup margin tS@tCKmin(t12) of the timing signal DWS2 is provided. This is because a period from the activation of the timing signal DWS1 until the start timing of the Valid Window of the write data WD(DQS) in a case (tDQSS+tDQSoffset=Nom) in which tDQSS+tDQSoffset is zero does not depend on the period tCK of the clock signal CK. In contrast thereto, the length itself of the Valid Window of the write data WD(DQS) is proportional to the period tCK of the clock signal CK. Therefore, if the timing signal DWS2 is activated at the time t12 in the case (tCKmin) in which the period tCK of the clock signal CK is the shortest, a hold margin tH@tCKmin(t12) of the timing signal DWS2 becomes considerably insufficient. However, in the present embodiment, since the timing signal DWS2 is activated at the time t11 earlier than the time t12 in the case (tCKmin) in which the period tCK of the clock signal CK is the shortest, a sufficient hold margin tH@tCKmin(t11) of the timing signal DWS2 can be provided as shown in FIG. 4.

When the timing signal DWS2 is activated at the time t11 earlier than the time t12, a setup margin tS@tCKmin(t11) of the timing signal DWS2 is decreased. However, since the absolute values of tDQSS and tDQSoffset are proportional to the period tCK of the clock signal CK, the difference between the start timing of the Valid Window of the write data WD(DQS) in the case (tDQSS+tDQSoffset=Nom) in which tDQSS+tDQSoffset is zero and the start timing of the Valid Window of the write data WD(DQS) in a case (tDQSS+tDQSoffset=Max) in which tDQSS+tDQSoffset is the largest is smaller as the period tCK of the clock signal CK is shorter. Accordingly, in the case (tCKmin) in which the period tCK of the clock signal CK is the shortest, the write data WD(DQS) can be accurately latched even in the case (tDQSS+tDQSoffset=Max) in which tDQSS+tDQSoffset is the largest.

Although various embodiments have been disclosed in the context of certain preferred embodiments and examples, it will be understood by those skilled in the art that the scope of the present disclosure extends beyond the specifically disclosed embodiments to other alternative embodiments and/or uses of the embodiments and obvious modifications and equivalents thereof. In addition, other modifications which are within the scope of this disclosure will be readily apparent to those of skill in the art based on this disclosure. It is also contemplated that various combination or sub-combination of the specific features and aspects of the embodiments may be made and still fall within the scope of the disclosure. It should be understood that various features and aspects of the disclosed embodiments can be combined with or substituted for one another in order to form varying modes of the disclosed embodiments. Thus, it is intended that the scope of at least some of the present disclosure should not be limited by the particular disclosed embodiments described above.

1. An apparatus comprising:
a data bus including a first portion having a timing domain which is controlled based on a first timing signal and further including a second portion having a timing domain which is controlled based on a second timing signal; and
a data transfer circuit coupled to the data bus, the data transfer circuit including a data driver between the first portion of the data bus and the second portion of the data bus and a timing control circuit coupled to the data driver,
wherein the timing control circuit includes a variable delay to add an amount of delay to a first control signal to generate a second control signal; and
wherein the data driver is configured to drive data from the second portion of the data bus to the first portion of the data bus responsive to the second control signal.

2. The apparatus of claim 1, wherein a delay amount of the timing control circuit is changed based on a frequency of the first timing signal.

3. The apparatus of claim 2, wherein the second timing signal has the same frequency as the first timing signal.

4. The apparatus of claim 1, further comprising:
a data terminal supplied with a write data from outside; and
an input receiver circuit configured to capture the write data on the data terminal,
wherein the data bus is configured to convey the write data output from the input receiver circuit.

5. The apparatus of claim 4, wherein the input receiver circuit is configured to capture the write data responsive to the second timing signal.

6. The apparatus of claim 5, wherein the second timing signal is a data strobe signal supplied from outside.

7. The apparatus of claim 6, wherein the first timing signal is a clock signal supplied from outside.

8. The apparatus of claim 7, further comprising:
a memory cell array; and
a write amplifier circuit configured to store the write data on the first portion of the data bus to the memory cell array responsive to a write timing signal,
wherein a timing domain of the write timing signal is controlled based on the first timing signal.

9. The apparatus of claim 1, wherein the delay amount of the timing control circuit is controlled based on a first internal signal.

10. The apparatus of claim 9,
wherein the timing control circuit includes a plurality of delay circuits having mutually different delay amounts, and
wherein one of the plurality of delay circuits is selected based on first internal signal.

11. The apparatus of claim 9, further comprising a mode register circuit configured to store the first internal signal.

12. The apparatus of claim 11, wherein the first internal signal relates to a frequency of the first timing signal.

13. An apparatus comprising:
a memory cell array;
a data bus configured to convey a write data to the memory cell array;
a data transfer circuit configured to transfer the write data to the data bus; and
a timing control circuit configured to activate the data transfer circuit after a first delay time elapsed after activating a timing signal according to a first operation mode, and activate the data transfer circuit after a second delay time different from the first delay time elapsed after activating the timing signal according to a second operation mode.

14. The apparatus of claim 13, further comprising a mode register circuit configured to select one of a plurality of operation modes including the first and second operation modes.

15. The apparatus of claim 13, wherein a timing domain of the timing signal is controlled based on a clock signal supplied from outside.

16. The apparatus of claim 15,
wherein the first operation mode is selected when the clock signal has a first frequency, and
wherein the second operation mode is selected when the clock signal has a second frequency different from the first frequency.

17. The apparatus of claim 16,
wherein the first frequency is higher than the second frequency, and
wherein the first delay time is shorter than the second delay time.

18. An apparatus comprising:
a memory cell array;
a control logic circuit configured to generate a first timing signal based on a clock signal in a data write operation;
a variable delay circuit configured to generate a second timing signal by delaying the first timing signal;
a data bus configured to convey a write data to the memory cell array; and
a data transfer circuit configured to transfer the write data to the data bus responsive to the second timing signal,
wherein a delay amount of the variable delay circuit when the clock signal has a first frequency is shorter than a delay amount of the variable delay circuit when the clock signal has a second frequency lower than the first frequency.

19. The apparatus of claim 18, wherein a delay amount of the variable delay circuit when the clock signal has the second frequency is shorter than a delay amount of the variable delay circuit when the clock signal has a third frequency lower than the second frequency.

20. The apparatus of claim 18, further comprising a mode register circuit configured to store a mode signal that relates to a frequency of the clock signal,
wherein a delay amount of the variable delay circuit is changed based on the mode signal.
